(19) United States
(12) Patent Application Publication
(10) Pub. No.: US 2024/0191342 A1
(43) Pub. Date: Jun. 13, 2024

(54) SUBSTRATE CARRIER FOR THIN FILM PROCESSING

(71) Applicant: INTEVAC, INC., Santa Clara, CA (US)

(72) Inventors: Samuel D. Harkness, IV, El Cerrito, CA (US); Thomas P. Nolan, Fremont, CA (US); Stephen M. Daly, Los Gatos, CA (US); Mike Anthony, Santa Clara, CA (US); Todd Morimoto, Santa Clara, CA (US)

(21) Appl. No.: 18/534,479

(22) Filed: Dec. 8, 2023

Related U.S. Application Data
(60) Provisional application No. 63/434,048, filed on Dec. 20, 2022.
(60) Provisional application No. 63/431,999, filed on Dec. 12, 2022.
(60) Provisional application No. 63/431,984, filed on Dec. 12, 2022.
(60) Provisional application No. 63/431,969, filed on Dec. 12, 2022.
(60) Provisional application No. 63/431,621, filed on Dec. 9, 2022.
(60) Provisional application No. 63/431,608, filed on Dec. 9, 2022.

(51) Int. Cl. C23C 14/50; C23C 14/34

(52) U.S. Cl. CPC C23C 14/50; C23C 14/34

(57) ABSTRACT

Embodiments of a substrate carrier are described. The substrate carrier includes a carrier tray having a deposition surface and a set of pedestal positions on the deposition surface. In some embodiments, the set comprises an N×M array of pedestal positions with N≥1 and M≥1. Each pedestal position is adapted to receive a corresponding substrate pedestal, and each pedestal has a working surface adapted to receive a substrate. One or more adjusters are positioned in a corresponding pedestal position. The adjuster can adjust a distance between the deposition surface and the working surface, an angular orientation of the working surface relative to the deposition surface, or both.

### CROSS-REFERENCE TO RELATED APPLICATIONS

This application relates to and claims priority benefit from U.S. Provisional Application Ser. No. 63/434,048, filed on Dec. 20, 2022, and from U.S. Provisional Application Ser. No. 63/431,999, filed on Dec. 12, 2022, and from U.S. Provisional Application Ser. No. 63/431,984, filed on Dec. 12, 2022, and from U.S. Provisional Application Ser. No. 63/431,969, filed on Dec. 12, 2022, and from U.S. Provisional Application Ser. No. 63/431,621, filed on Dec. 9, 2022, and from U.S. Provisional Application Ser. No. 63/431,608, filed on Dec. 9, 2022, the disclosures of which are incorporated herein in their entirety.

### TECHNICAL FIELD

The disclosed embodiments relate generally to thin-film deposition and in particular, but not exclusively, to a substrate carrier for thin-film processing.

### BACKGROUND

A growing variety of products with optical displays-including cell phones, smart watches, virtual reality (VR) goggles, and screens for pads, laptops and automobiles-require protection from damage during use and handling. One solution is to deposit a protective thin film optical overcoat onto the surface to simultaneously optimize the optical performance of the display and protect it from scratches, scuffs, and other damage.

High quality thin film materials can be produced for many applications using physical vapor deposition. High throughput of multiple layer thin film stacks, from a few nanometers up to several microns thick, can be achieved using magnetron cathodes in an in-line pass-through deposition system such as the one described in U.S. Pat. No. 10,679,883.

### SUMMARY

In one aspect, a substrate carrier includes a carrier tray having a deposition surface. A set of pedestal positions is present on the deposition surface, wherein each pedestal position is adapted to receive a corresponding substrate pedestal and wherein each pedestal has a working surface adapted to receive a substrate. In some embodiments, the set of pedestal positions comprises an N×M array wherein N≥1 and M≥1. One or more adjusters are each positioned in a corresponding pedestal position. Each adjuster can adjust a distance between the deposition surface and the working surface, an angular orientation of the working surface relative to the deposition surface, or both. In an embodiment, the substrate carrier also includes the one or more substrate pedestals, each positioned in a corresponding pedestal position. In another embodiment, the adjuster is positioned in each pedestal position to adjust the orientation of the substrate. In an embodiment, the adjuster includes one or more shims and in another embodiment the shims are wedge shims. In an embodiment a carrier base coupled to the carrier tray, and in another embodiment the carrier base includes a transport interface to couple the substrate carrier to a transport mechanism, and in yet another embodiment, the transport interface includes a plurality of toes, each toe having a different length. In embodiment at least one pedestal position of the set of pedestal positions is bounded by stops positioned around at least part of the pedestal position, and in another embodiment at least one pedestal position of the set of pedestal positions is a depression in the carrier tray.

In another aspect, a substrate carrier includes a carrier base with a carrier tray positioned and aligned on the carrier base. The carrier tray includes a deposition surface with an N×M set of pedestal positions on the deposition surface, wherein N≥1 and M≥1. One or more adjusters are each positioned in a corresponding pedestal position. Each adjuster can adjust a distance between the deposition surface and the working surface, an angular orientation of the working surface relative to the deposition surface, or both. One or more substrate pedestals are each positioned in a corresponding pedestal position, with each substrate pedestal having a working surface adapted to receive a substrate. In an embodiment, the carrier base includes a transport interface to couple the substrate carrier to a transport mechanism and in another embodiment the transport interface includes a plurality of toes, each toe having a different length. In an embodiment the carrier base includes a thick rigid web body. In an embodiment, the carrier base includes alignment pins that engage with corresponding alignment holes on the carrier tray, or the carrier base includes alignment holes that engage with corresponding alignment pins on the carrier tray. In an embodiment the adjuster is positioned in each pedestal position between the pedestal position and the corresponding substrate pedestal. In another embodiment the adjuster includes one or more shims, and in yet another embodiment the shims are wedge shims. In an embodiment at least one pedestal position of the set of pedestal positions is bounded by stops positioned around at least part of the pedestal position. In an embodiment at least one pedestal position of the set of pedestal positions is a depression in the carrier tray.

In another aspect, a deposition system includes a deposition chamber including a sputtering source and a transport system. A substrate carrier is coupled to the transport system to move one or more substrates through the deposition chamber. The substrate carrier includes a carrier base including a transport interface to couple the substrate carrier to the transport system. A carrier tray is positioned and aligned on the carrier base, and the carrier tray includes a deposition surface, an N×M set of pedestal positions on the deposition surface, wherein N≥1 and M≥1, and one or more adjusters, each positioned in a corresponding pedestal position. The adjuster can adjust a distance between the working surface and the sputtering source, an angular orientation of the working surface relative to the sputtering source, or both. One or more substrate pedestals are each positioned in a corresponding pedestal position, and each substrate pedestal has a working surface adapted to receive a substrate. In an embodiment, the carrier base includes a thick rigid web body. In an embodiment, the carrier base includes alignment pins that engage with corresponding alignment holes on the carrier tray, or includes alignment holes that engage with corresponding alignment pins on the carrier tray. In an embodiment, each adjuster is positioned in each pedestal position between the pedestal position and the corresponding substrate pedestal. In an embodiment the adjuster includes one or more shims, and in another embodiment the shims are wedge shims. In an embodiment, at least one pedestal position of the set of pedestal positions is bounded by stops positioned around at least part of the pedestal position. In an embodiment, at least one pedestal position of the set of pedestal positions is a depression in the carrier tray. In an embodiment, the carrier base includes a transport interface to couple the substrate carrier to a transport mechanism, and in another embodiment the transport interface includes a plurality of toes, each toe having a different length.

In another aspect, a process comprises providing a carrier tray having a deposition surface with an N×M set of pedestal positions on the deposition surface, wherein N≥1 and M≥1. Each pedestal position is adapted to receive a corresponding substrate pedestal, each pedestal having a working surface adapted to receive a substrate. The process further includes positioning an adjuster in at least one pedestal position of the set of pedestal positions, and setting each adjuster to adjust a distance between the deposition surface and the working surface, an angular orientation of the working surface relative to the deposition surface, or both. In an embodiment, the process further includes positioning one or more substrate pedestals in each pedestal position in which an adjuster is positioned. In an embodiment, positioning an adjuster in at least one pedestal position of the set of pedestal positions comprises positioning the adjuster in each pedestal position between the pedestal position and the corresponding substrate pedestal. In an embodiment the adjuster includes one or more shims, and in another embodiment the shims are wedge shims. In an embodiment, at least one pedestal position of the set of pedestal positions is bounded by stops positioned around at least part of the pedestal position. In an embodiment, at least one pedestal position of the set of pedestal positions is a depression in the carrier tray. In an embodiment the process further includes coupling a carrier base to the carrier tray, in another embodiment the carrier base includes a transport interface to couple the substrate carrier to a transport mechanism, and in another embodiment the transport interface includes a plurality of toes, each toe having a different length.

In another aspect, a process includes positioning a carrier tray on a carrier base, the carrier tray including a deposition surface and an N×M set of pedestal positions on the deposition surface, wherein N≥1 and M≥1. The process further includes positioning an adjuster in at least one pedestal position of the set of pedestal positions, and positioning a substrate pedestal in each of the at least one pedestal positions having an adjuster, wherein each substrate pedestal has a working surface adapted to receive a substrate and wherein each adjuster can adjust a distance between the deposition surface and the working surface, an angular orientation of the working surface relative to the deposition surface, or both. In an embodiment, the process further comprises attaching a transport interface to the carrier base, the transport interface being configured to couple the carrier base to a transport mechanism, and in another embodiment the transport interface includes a plurality of toes, each toe having a different length. In an embodiment, positioning the carrier tray on the carrier base comprises engaging alignment pins on the carrier base with corresponding alignment holes on the carrier tray, or engaging alignment holes on the carrier base with corresponding alignment pins on the carrier tray. In an embodiment, positioning an adjuster in at least one pedestal position of the set of pedestal positions comprises positioning the adjuster in each pedestal position between the pedestal position and the corresponding substrate pedestal. In an embodiment, the adjuster includes one or more shims and in another embodiment the shims are wedge shims. In an embodiment at least one pedestal position of the set of pedestal positions is bounded by stops positioned around at least part of the pedestal position. In an embodiment, at least one pedestal position of the set of pedestal positions is a depression in the carrier tray.

In another aspect, a process includes positioning a carrier tray on a carrier base, the carrier tray including a deposition surface and an N×M set of pedestal positions on the deposition surface, wherein N≥1 and M≥1. The process further includes positioning an adjuster in at least one pedestal position of the set of pedestal positions and positioning a substrate pedestal in each of the at least one pedestal position having an adjuster, wherein each substrate pedestal has a working surface adapted to receive a corresponding substrate. The process further includes coupling the carrier base to a transport system of a deposition chamber, the deposition chamber including a sputtering source, and using the adjuster to adjust a distance between the deposition surface and the sputtering source, an angular orientation of the working surface relative to the sputtering source, or both. In an embodiment, the process further comprises moving the substrates through the deposition chamber. In an embodiment, positioning the carrier tray on the carrier base comprises engaging alignment pins on the carrier base with corresponding alignment holes on the carrier tray, or engaging alignment holes on the carrier base with corresponding alignment pins on the carrier tray. In an embodiment, positioning an adjuster in at least one pedestal position of the set of pedestal positions comprises positioning the adjuster in each pedestal position between the pedestal position and the corresponding substrate pedestal. In an embodiment, the adjuster includes one or more shims, and in another embodiment the shims are wedge shims. In an embodiment, at least one pedestal position of the set of pedestal positions is bounded by stops positioned around at least part of the pedestal position. In an embodiment, at least one pedestal position of the set of pedestal positions is a depression in the carrier tray. In an embodiment, coupling the carrier base to the transport system comprises coupling a transport interface attached to the carrier base to the transport system, and in another embodiment the transport interface includes a plurality of toes, each toe having a different length.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified. Drawings are not to scale unless otherwise indicated.

FIG. 1 is a cross-sectional diagram of an embodiment of a plasma deposition chamber.

FIG. 2 is an exploded perspective drawing of an embodiment of a substrate carrier.

FIGS. 3A-3B are perspective drawings of an embodiment of a carrier base usable with the embodiment of a substrate carrier shown in FIG. 2. FIG. 3A shows an embodiment of the carrier base, FIG. 3B an embodiment of the carrier base's transport interface with a transport system.

FIG. 3C is a schematic of an embodiment of a transport system for substrates that is usable with the embodiment of a transport interface shown in FIG. 3B.

FIGS. 4A-4C are view of an embodiment of an embodiment of a carrier tray that can be used with the embodiment of a carrier base shown in FIGS. 3A-3B. FIG. 4A is a plan view of a tray, FIGS. 4B-4C are cross-sectional views of embodiments of pedestal positions on a tray.

FIG. 5 is a perspective view of an embodiment of a substrate pedestal that can be used with the embodiment of a carrier tray shown in FIG. 4.

FIGS. 6A-6E are cross-sectional views of embodiments of adjusters for adjusting the angular orientation, height, or both, of a pedestal relative to a carrier tray.

### DETAILED DESCRIPTION

Embodiments are described of a substrate carrier for use in thin-film deposition. Specific details are described to provide an understanding of the embodiments, but one skilled in the relevant art will recognize that the invention can be practiced without one or more of the described details or with other methods, components, materials, etc. In some instances, well-known structures, materials, or operations are not shown or described in detail but are nonetheless encompassed within the scope of the invention.

Reference throughout this specification to “one embodiment” or “an embodiment” means that a described feature, structure, or characteristic can be included in at least one described embodiment, so that appearances of “in one embodiment” or “in an embodiment” need not refer to the same embodiment. Furthermore, the particular features, structures, or characteristics may be combined in any suitable manner in one or more embodiments.

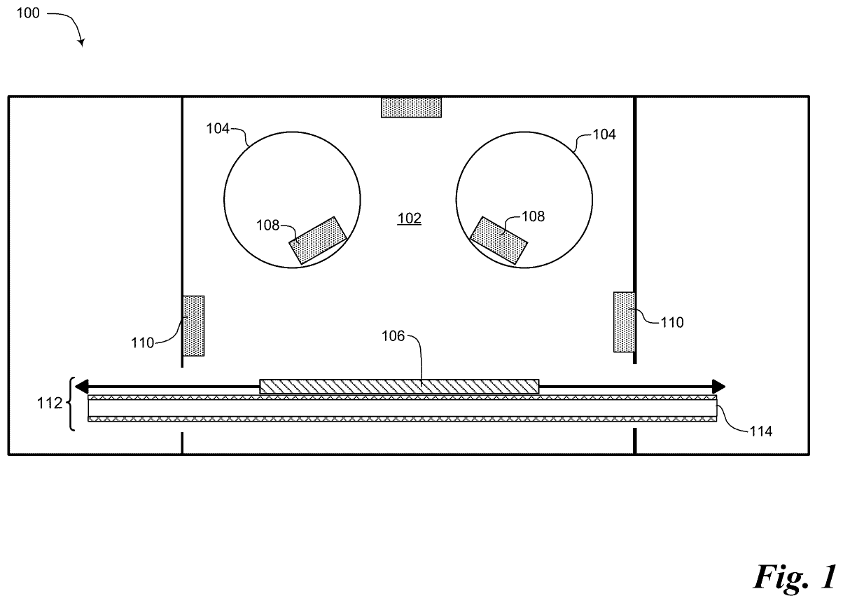

FIG. 1 illustrates an embodiment of a magnetron plasma deposition chamber 100. Chamber 100 includes a vacuum chamber 102, constructed for vacuum processing in the form of physical vapor deposition (PVD). Dual cylindrical magnetron sputtering, and more specifically reactive processing, deploys with sufficient symmetry to facilitate pass-by or inline film deposition. Twin cathodes 104 form a sputtering source that imposes a flux of adsorbate material upon a substrate carrier 106 passing by at a prescribed speed (e.g., 10 mm/s). The flux of absorbate material is generated with classical magnetron dynamics, with the magnetically-confined region defined by the magnetrons 108 enabling efficient ionization of gas species such as Argon (Ar), Krypton (Kr), Xenon (Xe), Neon (Ne), Helium (He), etc., which are then accelerated toward the cathode 110 held at potential (e.g., >˜−300 V). The impact of these accelerated species imparts sufficient energy to dislodge previously bonded material into the vacuum space where they then become available for deposition on substrates positioned on substrate carrier 106. The targets mounted onto cathodes 104 are made of material that ultimately deposits on the intended part with identical stoichiometry.

One use of the above-mentioned setup is to convert a material from the cathode stoichiometry to a film comprising an adjusted oxidation state (compared to the original material). Such films generally become dielectric and often present opportunities in the fields of optics, tribology and diffusion to name a few. The most common practice involves introduction of reactive gases (e.g., Oxygen, Nitrogen, Hydrogen, etc.) during processing that ultimately form the desired bonding and resultant stoichiometry in the film.

Chamber 100 has an in-line pass-through system that includes a carrier transport system 112 enabling substrate carrier 106 to be transported through chamber 102, passing in front of one or more of said cathodes 104 and receiving material deposition during the pass-by process. An inline pass-through PVD chamber as described above has a transport direction or axis along the travel path of the substrate carrier and a perpendicular transverse direction or axis along the direction parallel to the cathode rotational axis. In the illustrated embodiment, the transport system includes rails 114 on which substrate carrier 106 can move, but other transport systems can be set up differently.

As substrate carrier 106 moves through the chamber, material deposited from the cathodes (i.e., the sputtering source) shown will deposit onto the various parts of the carrier plane at many different angles and particle/adatom energies that depend on the geometry of the cathodes and chamber as well as process parameters including the gas species and pressures, and the magnetic field from the magnetrons 108. The properties of deposited film also depend on the deposition angle with respect to the target surface, the central axis of the magnetron magnetic confinement, the path length traversed in the plasma the path length traversed between the plasma and the substrate, and the effective carrier gas pressure and scattering cross-sections within the deposition chamber and inside of the plasma. The result is that the adatom energy of sputter material and correspondingly the film properties of the sputtered thin film including hardness, density, stress, refractive index, and optical absorption; as well as angular-dependent surface coverage, reflected back-side sputter and heating of a deposited substrate can vary significantly depending on the position of the substrate on the carrier and the geometry and material properties of a pedestal on which the substrate is placed. It is thus desired to design substrate carriers and pedestals that may be easily adjustable to locally optimize the film properties of substrates placed on pedestals at each lateral position of the carrier plane.

To increase throughput and production efficiency of a deposition process it is desirable to place as many substrates on a carrier as possible. But the properties of deposited material vary from one position in the chamber to another owing to geometrical and process differences that may be unavoidable. Thus, substrates placed at different positions on the carrier may receive different or non-uniform film coatings that degrade performance of the film at some locations on the carrier. Furthermore, film quality can be degraded if the carrier allows the substrate to receive deposition of material on the bottom of the substrate or preferentially on one side of a three dimensional part; or to maintain too much or too little heat from the deposition process. There is thus a need for substrate carrier designs that improve quality and uniformity of films deposited throughout a desired area of a substrate carrier.

The figures, and their description below, together illustrate embodiments of a substrate carrier that can be used together with a transport system to move substrates through an in-line deposition system such as chamber 100 so that thin films can be deposited or otherwise formed on the substrates. The embodiments described below do not limit geometries, tools, design features, or applications where alternative embodiments of the invention can be employed.

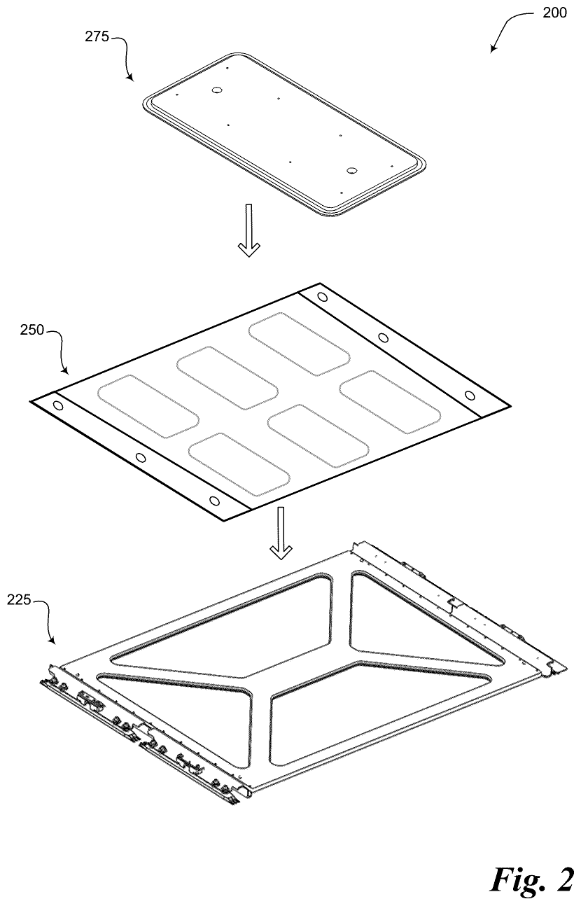

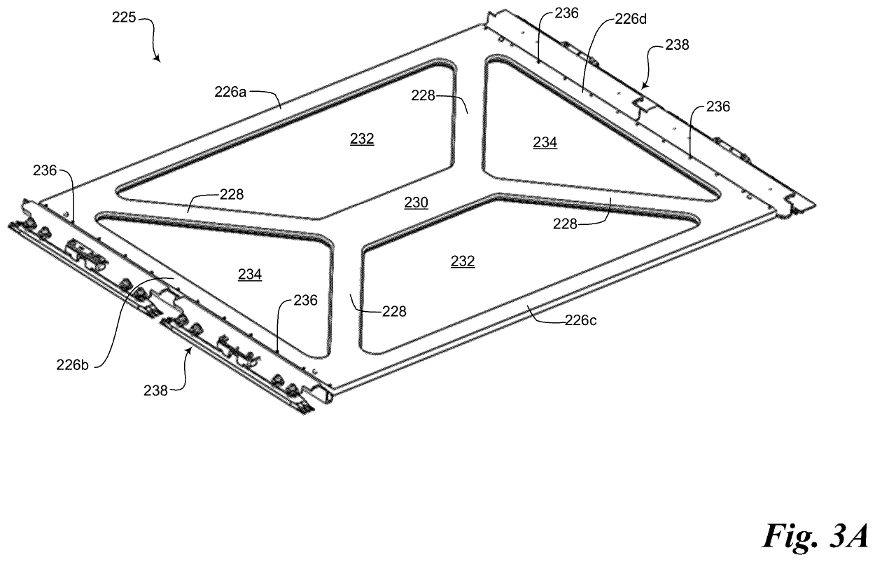

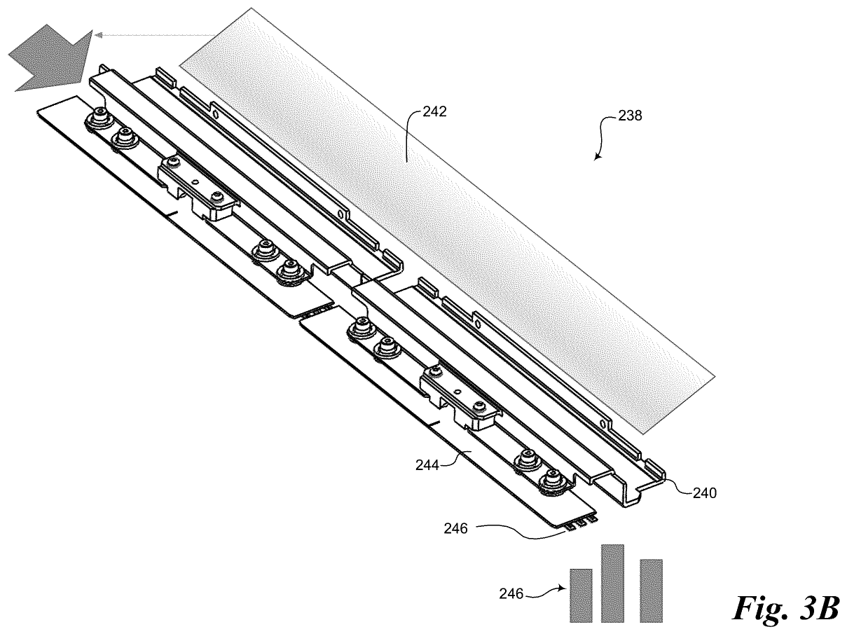

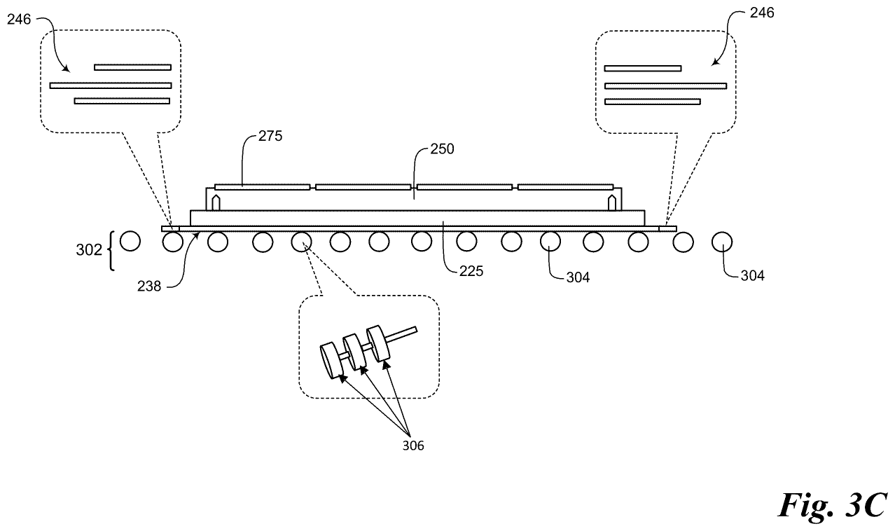

FIG. 2 illustrates in exploded view the overall construction of an embodiment of a substrate carrier 200. The substrate carrier includes three main parts: a carrier base 225, a carrier tray 250, and one or more substrate pedestals 275. The three main parts are assembled as illustrated to form the substrate carrier. Carrier base 225 is the lowermost part of the substrate carrier that supports the other two main parts and also provides an interface by which the substrate carrier can be coupled to a transport system such as the rail system shown in FIG. 1. Details of an embodiment of carrier base 225 are discussed below in connection with FIGS. 3A-3B.

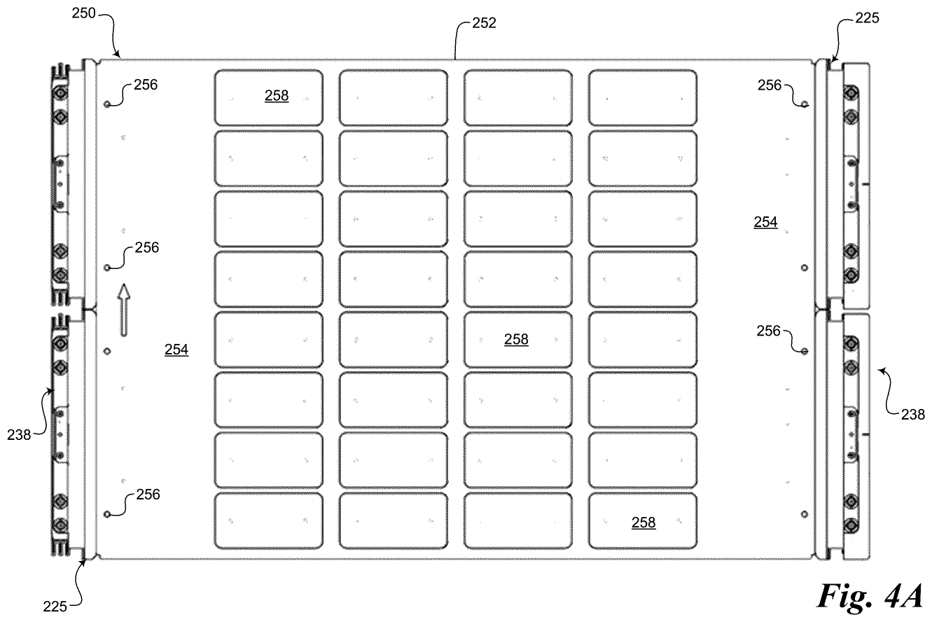

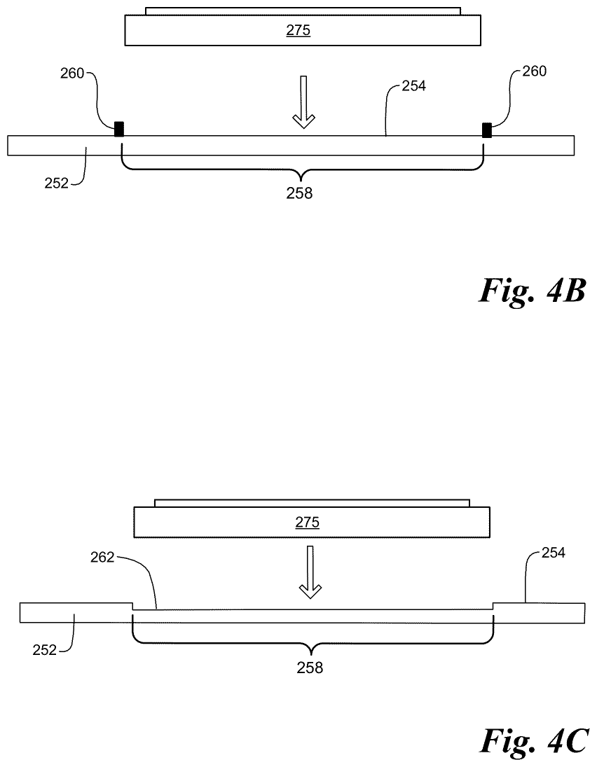

Carrier tray 250 is a middle part of the substrate carrier that provides an interface between the carrier base and the substrate pedestals and also supports the substrate pedestals (here shown with arrangement supporting six pedestals as but one example). Carrier tray 250 is placed on carrier base 225, using alignment features such as pins and holes, to ensure that the carrier tray is securely engaged with the carrier base and to ensure that the tray's alignment with the carrier base is accurate and repeatable. Details of an embodiment of carrier tray 250 are discussed below in connection with FIGS. 4A-4C.

One or more substrate pedestals 275 are placed on carrier tray 250 to complete the substrate carrier. The illustrated embodiment shows only a single substrate pedestal being assembled onto carrier tray 250, but other embodiments can have multiple pedestals per carrier tray. Details of an embodiment of carrier pedestal 275 are discussed below in connection with FIG. 5.

FIGS. 3A-3B illustrate details of an embodiment of a carrier base 225. FIG. 3A illustrates the carrier base, while FIG. 3B the details of an embodiment of a transport interface by which the carrier base can be coupled to a transport system such as the rail-based transport system illustrated in FIG. 1.

Carrier base 225 is quadrilateral in shape (here rectangular), although other embodiments need not be quadrilateral. The carrier base includes a thick rigid web body with edge supports 226a-226d, each positioned along one edge of the quadrilateral. The thickness of the rigid web body will depend on the material properties of the material used, the configuration of supports, and the expected loads. Generally, the thickness can be set so that the rigid web body can support the carrier tray, substrate pedestals, adjusters, and substrates with little or no deformation, so that the position and orientation of the substrates is not substantially affected by deformation of the carrier base. In one embodiment, for instance, the thickness of the rigid web body is greater than the thickness of the carrier tray, but in other embodiments the rigid web body can have the same or less thickness than the carrier tray, depending on the configuration and material of the rigid web body. A central support 230 is connected to edge supports 226 by diagonal supports 228. The illustrated embodiment has four diagonal supports 228 that connect central support 230 to the corners where each pair of edge supports 226 meet. This arrangement results in four voids or open areas—two trapezoidal voids 232 and two triangular voids 234—that reduce weight while also providing for support of carrier trays 250 and pedestals 275 without sagging or warping at process temperatures. Other embodiment of carrier base 225 can configure the carrier base differently than shown—for instance, with other configurations of supports 226, 228, and 230, or with different numbers of supports, different support shapes and dimensions, and different connections between supports. Transport interfaces 238 are positioned on opposite edges 226b and 226d in the illustrated embodiment, but can be positioned differently in other embodiments or when used with other types of transport system.

Carrier base 225 also includes alignment pins 236 for accurate and repeatable positioning, and rapid loading and unloading, of other substrate carrier components such as carrier tray 250. Generally, other components that will be placed on carrier base 225 will have corresponding alignment holes to receive and engage alignment pins 236. In the illustrated embodiment alignment pins 236 are positioned on opposite edges 226b and 226d of the carrier base, but in other embodiments the alignment pins can be positioned differently and distributed differently than shown. In other embodiments, carrier base can include alignment holes instead of alignment pins, in which case the other components can include alignment pins instead of alignment holes. In still other embodiments, other alignments features can be used, such as corner stops that engage corners of the carrier tray or edge stops that engage edges of the tray.

FIG. 3B illustrates details of an embodiment of transport interface 238, by which carrier tray 225 is coupled to a transport system. Transport interfaces 238 couple the carrier base to a rail transport system through carrier feet 244 and include a drive-side guide 240 that overlaps chamber guide flange 242 to guide the substrate carrier along a transport direction. Transport interfaces 238 also include transport feet 244 with magnetic toes 246, shown in the expanded view. In one embodiment, magnetic toes 246 are made of magnetic material and ride on wheels positioned within the chamber. The magnetic toes 246 have different toe lengths to increase the coefficient friction and come off magnetic wheels at different times in response to applied force as the carrier moves from one section to the other. This makes the transition from one section to another smoother, since the toes move from one wheel to the next in sequence, rather than all together at the same time.

FIG. 3C illustrates an embodiment of a substrate carrier such as carrier 200 used with a transport system. As described above, substrate carrier 200 includes three main parts: carrier base 225, carrier tray 250 and one or more substrate pedestals 275. The substrate carrier uses a transport interface such as interface 238, described above, to couple to a transport system 302. Transport interface 238 engages with multiple magnetic wheel assemblies 304 of the transport system, and each magnetic wheel assembly includes three wheels 306. Each carrier foot 244 includes three magnetic toes 246, each of which is a magnetic bar that rides on one of the three wheels 306. The three magnetic toes 246 have different lengths; in the illustrated embodiment the central toe is the longest and one of the outer toes the shortest, but in other embodiments the toes could be ordered differently than shown. The three toes increase the coefficient friction and come off magnetic wheel at different times in response to applied force as the carrier moves from one section of transport system 302 to another.

In addition to the features described above, in other embodiments carrier base 225 can include one or more of the following features: light weight; stiff, inexpensive machinable design and material; and adaptable foot design for stable connectivity to transport system.

FIGS. 4A-4C illustrate embodiments of a carrier tray 250. FIG. 4A shows carrier tray 250 positioned on carrier base 225 and illustrates its basic construction. FIGS. 4B-4C illustrate embodiments of pedestal positions on the carrier tray.

Carrier tray 250 includes a thin tray 252 with a substantially flat deposition surface 254 that can provide a uniform sputter surface for deposition. In some embodiments, deposition surface 254 can include a rough surface to minimize coating delamination, including arc spray surface coating, bead blasting, and other roughening mechanisms. In an embodiment where carrier base 225 includes alignment pins 236, thin tray 252 can include alignment holes 256 that engage the alignment pins to accurately and repeatably align the carrier tray on the carrier base. The illustrated embodiment has eight alignment holes 256 positioned along opposite edges of thin tray 252, with four alignment holes along each edge. Other embodiment can use a different number of alignment holes and can position and distribute them differently than shown. And in embodiments where carrier base 225 uses alignment holes instead of alignment pins 236, carrier tray 250 can correspondingly use alignment pins instead of alignment holes 256.

Carrier tray 250 also includes pedestal positions 258. The pedestal positions are an N×M set of positions, wherein N≥1 and M≥1. In an embodiment where M=N=1 there is a single pedestal position, but embodiments where M≥1, N≥1, or both, will have multiple pedestal positions. The illustrated embodiment has an 8×4 set of positions 258 arranged in a regular array, but other embodiments can of course have different numbers of positions (see, e.g., FIG. 2). In other embodiments positions 258 also need not form a regular array; they can form an irregular array, or no array at all. In one embodiment of carrier tray 250 all pedestal positions are the same—same size, same shape, same delineation—but in other embodiments all pedestal positions need not be the same.

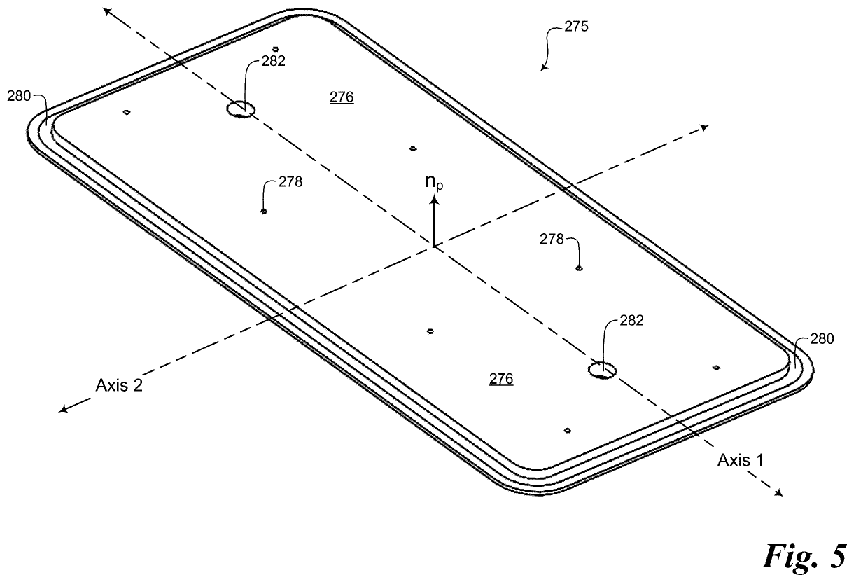

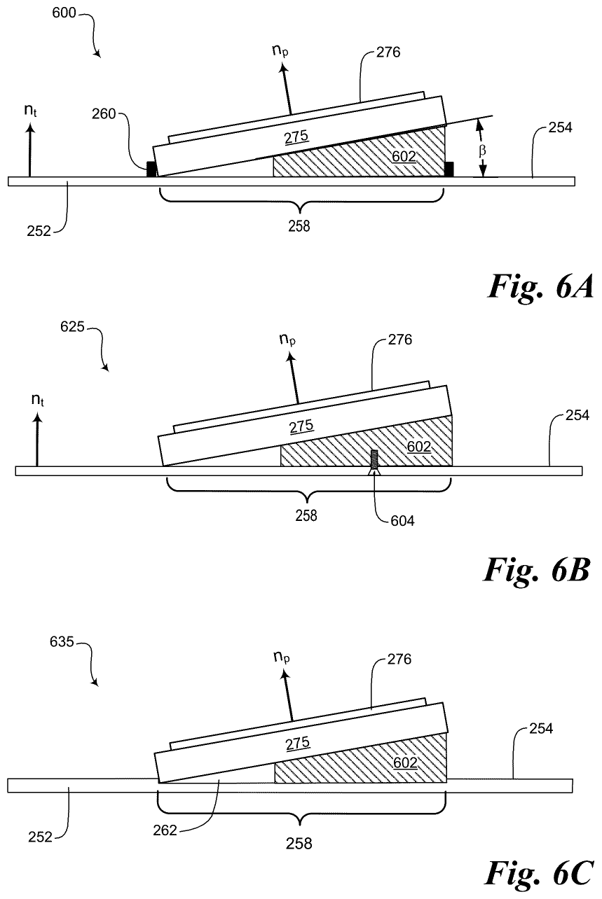

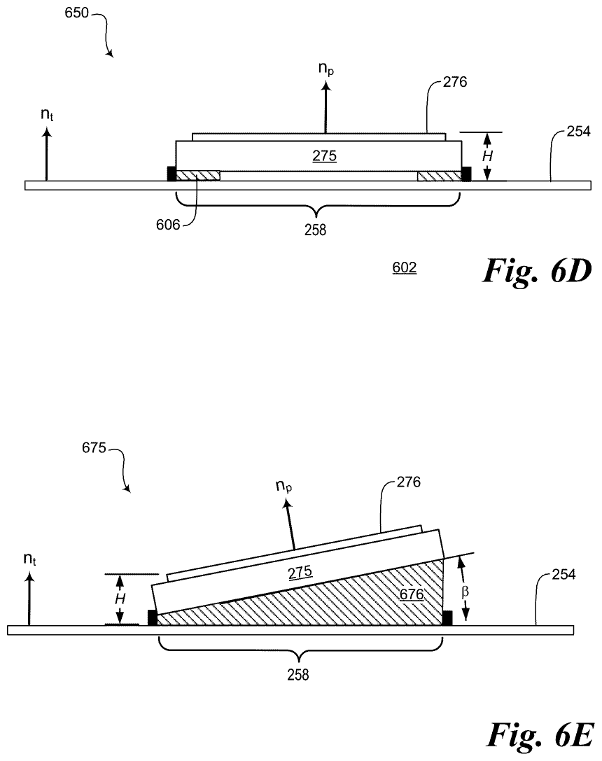

FIGS. 4B-4C illustrate embodiments of pedestal positions 258. Each pedestal position 258 is sized and shaped to receive a corresponding pedestal 275, but the pedestal positions can be delineated differently in different embodiments. In the embodiment of FIG. 4B, for instance, pedestal position 258 can be bounded by stops 260 positioned around some or all of the position's perimeter. In the embodiment of FIG. 4C, a pedestal position 258 can be bounded by the edges of a surface depression 262 formed in thin tray 252. In other embodiments the pedestal positions can be formed differently; for instance, they can simply be marked on deposition surface 254. As further discussed below in connection with FIGS. 6A-6D, one or more pedestal positions 258 can include an adjuster by which the height, angular orientation, or both, of the pedestal's working surface can be adjusted. Adjusters positioned in the pedestal positions provide a mechanism to adjust the target-to-substrate distance or tilt of each substrate normal away from directly perpendicular to the substrate based on the height of the pedestal mounts.

In addition to the above features, carrier tray 250 can include one or more of the following features: light weight, adjustable shape; and thermal properties; adjustable mounting positions for pedestal strips, tilted shims or individual pedestals; disposable and compatible with arc spray for particle reduction without affecting substrate environment.

FIG. 5 illustrates an embodiment of a carrier pedestal 275. Pedestal 275 can include a smooth and substantially flat working surface 276 to receive a substrate placed on the pedestal. Vent holes 278 prevent trapped gas from affecting part alignment upon vacuum system entry. Trench 280 is positioned to just cover the edge of the substrate and prevent edge or back-side deposition without shadowing the front-side deposition. Pedestal 275 can be made of a material with high thermal conductivity, such as aluminum, for temperature control during deposition.

Pedestal 275 has two orthogonal axes, Axis 1 and Axis 2, and the angular orientation of working surface 276 can be adjusted by rotating the pedestal about either or both axes. Put differently, working surface 276 has a normal vector nₚ whose direction can be changed by rotating the pedestal about Axis 1, Axis 2, or both Axis 1 and Axis 2. When a substrate is mounted or held on working surface 276, changing the orientation of the working surface results in a corresponding change of orientation of the substrate. Rotation and translation of pedestal 275 can be accomplished with an adjuster in a pedestal position in which pedestal 275 is put. Adjusters can be any device, mechanism, or object that enables rotation and translation of the pedestal relative to the tray. Some embodiments of adjusters can use simple or complex mechanisms that can be set to any position or angle, while other embodiments can be simple objects such as blocks or shims. Some embodiments of adjusters are shown in FIGS. 6A-6D.

The illustrated embodiment of carrier pedestal 275, with substantially flat working surface 276, is appropriate for mounting a three-dimensional substrate with a mostly flat surface and curves near the edges. But in other embodiments working surface 276 need not be flat; mounts for a wide variety of substrates of different shapes and sizes, having flat surfaces or complex three-dimensional shapes, can be constructed. Whether working surface 276 is flat or not, its angular orientation can be adjusted as described above using the adjuster in the corresponding pedestal position.

In addition to the above features, carrier pedestal 275 can include one or more the following features: optimized shape and rim design to shield substrate edges and bottom surfaces from unwanted deposition; pedestal thermal mass, surface roughness and material selection can be optimized for desired heat removal during deposition. That is, in combination with adjuster embodiments described in conjunction with FIG. 6, pedestal embodiment material composition and thickness can be adjusted to select optimal thermal conductivity and thermal mass to independently optimize deposition conditions including substrate temperature and target to substrate distance for parts processed at each pedestal position. Such control methodology, for example enables samples on each pedestal across the carrier to have substantially the same substrate temperature even in cases where the sputter process temperature and carrier tray temperature may vary across the process chamber positions.

In one embodiment, an infrared thermal map image of the top surface of each carrier can be obtained as it exits the sputter system after processing, with or without the pedestals in place. The temperature is determined at each pedestal position. The pedestal temperature can be equalized while maintaining target-to-substrate distance by employing a thinner, lower thermal mass pedestal combined with a thicker adjuster at the cooler pedestal locations and employing a thicker, higher thermal mass pedestal combined with a thinner adjuster at the hotter pedestal locations. In many preferred embodiments, the production heating profile is stable from carrier to carrier so the same pedestal and adjuster selections may be applied universally to production carriers. In such embodiments, continuous improvement of the pedestal temperature uniformity can be achieved and maintained as needed to correct for process drift throughout a production cycle.

The substrate temperature on each pedestal of a carrier is collected as it exits the system, and according to a preferred statistical process control evaluation, a pedestal position that is determined to be consistently too hot or too cold can be swapped out for a correspondingly thicker or thinner pedestal at that position for all subsequent carriers entering the system. In some embodiments, a clearly marked series of pedestal and adjuster combinations providing different heating rates by methods including but not limited to thickness as previously described, are pre-defined, and can be easily and conveniently selected during manual or robot carrier loading.

FIGS. 6A-6D illustrate embodiments of adjusters in a pedestal position. The adjusters that can be used to adjust the angular orientation and position of the pedestal and its working surface relative to the carrier tray through rotation, translation, or both, of the pedestal relative to the carrier tray. By adjusting the position and orientation of the working surface, the substrate normal axis can be tilted to match the local average lateral angle of incidence and optimize coverage uniformity. The substrate surface plane can also be raised or lowered to adjust sputter source-to-substrate distance to tune both deposition and film stress. When used in a deposition chamber such as the one shown in FIG. 1, adjustment of the working surface's position and angular orientation relative to the carrier tray results in a corresponding adjustment of the working surface's position and angular orientation relative to the sputtering source.

FIG. 6A illustrates an embodiment of an adjuster 600 positioned between pedestal position 258 and its corresponding pedestal 275. Adjuster 600 uses a wedge shim 602 with a pedestal position such as the one of FIG. 4B, where the pedestal position is delimited by stops 260. Wedge shim 602 with wedge angle β is positioned in pedestal position 258 abutting a stop 260, and pedestal 275 is then lowered onto the wedge shim. Stops 260 prevent the pedestal and wedge shim from sliding laterally. The wedge shim changes the orientation of working surface 276, with the shim's angle β tilting the working surface's normal vector nₚ by β degrees relative to the normal vector nₜ of deposition surface 254. In different embodiments, wedge angle β can be any value between 0 degrees and 75 degrees. Also, in some embodiments wedge shim 602 can be a compound wedge that simultaneously tilts normal vector about multiple axes, for instance about Axis 1 and Axis 2 shown in FIG. 5. Wedge shim 602 can include holes therein (not shown in the figure) that fluidly couple with pedestal vent holes 278 (see FIG. 5) to allow the vent holes to perform their venting function.

FIG. 6B illustrates another embodiment of an adjuster 625. Adjuster 625 is in most respects similar to adjuster 600, but can be used in embodiments where pedestal position 258 is not delimited by a stop. In this embodiment, then, wedge shim 602 can be held in place by a fastener 604 inserted through tray 252 to prevent the shim from moving laterally.

FIG. 6C illustrates another embodiment of an adjuster 635. Adjuster 635 is in most respects similar to adjuster 600, but can be used in embodiments where pedestal position 258 delimited by surface depression 262 formed in tray 252. In this embodiment, then, wedge shim 602 can be held in place by the edges of surface depression 262, so that the edges prevent the shim and the substrate pedestal from moving laterally.

FIG. 6D illustrates another embodiment of an adjuster 650. Adjuster 650 uses one or more flat shims 606 to translate working surface 276 relative to deposition surface 254 without changing its angular orientation. Put differently, flat shims 606 increase the height Hof working surface 276 above deposition surface 254, without changing the angle of the working surface's normal vector nₚ relative to the normal vector nₜ of the deposition surface.

FIG. 6E illustrates another embodiment of an adjuster 675 that adjusts both the angular orientation and height of working surface 276. Adjuster 675 use a wedge shim 676 of trapezoidal cross section and extends the shim across the entire pedestal position, so that working surface 276 is both translated and rotated. Put differently, trapezoidal wedge shim 676 both increases the height H of working surface 276 above deposition surface 254 and changes the angular orientation of the working surface's normal vector nₚ relative to the normal vector nₜ of the deposition surface.

With the above disclosure, a substrate carrier is provided, comprising: a carrier base; a carrier tray positioned and aligned on the carrier base, the carrier tray including: a deposition surface, a set of pedestal positions on the deposition surface, and one or more adjusters, each positioned in a corresponding pedestal position, wherein each adjuster can adjust a distance between the deposition surface and the working surface, an angular orientation of the working surface relative to the deposition surface, or both; and one or more substrate pedestals, each positioned in a corresponding pedestal position, wherein each substrate pedestal has a working surface adapted to receive a substrate. The carrier base includes a transport interface to couple the substrate carrier to a transport mechanism. The transport interface includes a plurality of toes, each toe having a different length. The carrier base includes a thick rigid web body. The carrier base includes alignment pins that engage with corresponding alignment holes on the carrier tray, or wherein the carrier base includes alignment holes that engage with corresponding alignment pins on the carrier tray. The at least one adjuster is positioned in at least one of the pedestal position between the pedestal position and the corresponding substrate pedestal. The adjuster includes one or more shims. The shims are wedge shims. The at least one pedestal position of the set of pedestal positions is bounded by stops positioned around at least part of the pedestal position. The at least one pedestal position of the set of pedestal positions is a depression in the carrier tray. The set comprises an N×M array of pedestal positions, wherein N≥1 and M≥1.

Also, with the above disclosure a process is provided, comprising: providing a carrier tray having a deposition surface with an N×M set of pedestal positions on the deposition surface, wherein N≥1 and M≥1, wherein each pedestal position is adapted to receive a corresponding substrate pedestal and wherein each pedestal has a working surface adapted to receive a substrate; positioning an adjuster in at least one pedestal position of the set of pedestal positions; and setting each adjuster to adjust a distance between the deposition surface and the working surface, an angular orientation of the working surface relative to the deposition surface, or both. The process further comprising positioning one or more substrate pedestals in each pedestal position in which an adjuster is positioned. The process wherein positioning an adjuster in at least one pedestal position of the set of pedestal positions comprises positioning the adjuster in each pedestal position between the pedestal position and the corresponding substrate pedestal. The process wherein pedestal thickness and adjuster height of at least two pedestal positions on a carrier are selected at different values to provide equalized substrate temperature after sputter is completed. The process wherein the adjuster includes one or more shims. The process wherein the shims are wedge shims. The process wherein at least one pedestal position of the set of pedestal positions is bounded by stops positioned around at least part of the pedestal position. The process wherein at least one pedestal position of the set of pedestal positions is a depression in the carrier tray. The process further comprising coupling a carrier base to the carrier tray. The process wherein the carrier base includes a transport interface to couple the substrate carrier to a transport mechanism. The process wherein the transport interface includes a plurality of toes, each toe having a different length.

A further process is disclosed, comprising: positioning a carrier tray on a carrier base, the carrier tray including a deposition surface and an N×M set of pedestal positions on the deposition surface, wherein N≥1 and M≥1; positioning an adjuster in at least one pedestal position of the set of pedestal positions; and positioning a substrate pedestal in each of the at least one pedestal positions having an adjuster, wherein each substrate pedestal has a working surface adapted to receive a substrate and wherein each adjuster can adjust a distance between the deposition surface and the working surface, an angular orientation of the working surface relative to the deposition surface, or both. The process further comprising attaching a transport interface to the carrier base, the transport interface being configured to couple the carrier base to a transport mechanism. The process wherein the transport interface includes a plurality of toes, each toe having a different length. The process wherein positioning the carrier tray on the carrier base comprises engaging alignment pins on the carrier base with corresponding alignment holes on the carrier tray, or engaging alignment holes on the carrier base with corresponding alignment pins on the carrier tray. The process wherein positioning an adjuster in at least one pedestal position of the set of pedestal positions comprises positioning the adjuster in each pedestal position between the pedestal position and the corresponding substrate pedestal. The process wherein the adjuster includes one or more shims. The process wherein the shims are wedge shims. The process wherein at least one pedestal position of the set of pedestal positions is bounded by stops positioned around at least part of the pedestal position. The process wherein at least one pedestal position of the set of pedestal positions is a depression in the carrier tray.

An additional process is disclosed, comprising: positioning a carrier tray on a carrier base, the carrier tray including a deposition surface and an N×M set of pedestal positions on the deposition surface, wherein N≥1 and M≥1; positioning an adjuster in at least one pedestal position of the set of pedestal positions; positioning a substrate pedestal in each of the at least one pedestal position having an adjuster, wherein each substrate pedestal has a working surface adapted to receive a corresponding substrate; coupling the carrier base to a transport system of a deposition chamber, the deposition chamber including a sputtering source; and using the adjuster to adjust a distance between the deposition surface and the sputtering source, an angular orientation of the working surface relative to the sputtering source, or both. The process further comprising moving the substrates through the deposition chamber. The process wherein positioning the carrier tray on the carrier base comprises engaging alignment pins on the carrier base with corresponding alignment holes on the carrier tray, or engaging alignment holes on the carrier base with corresponding alignment pins on the carrier tray. The process wherein positioning an adjuster in at least one pedestal position of the set of pedestal positions comprises positioning the adjuster in each pedestal position between the pedestal position and the corresponding substrate pedestal. The process wherein the adjuster includes one or more shims. The process wherein the shims are wedge shims. The process wherein at least one pedestal position of the set of pedestal positions is bounded by stops positioned around at least part of the pedestal position. The process wherein at least one pedestal position of the set of pedestal positions is a depression in the carrier tray. The process wherein coupling the carrier base to the transport system comprises coupling a transport interface attached to the carrier base to the transport system. The process wherein the transport interface includes a plurality of toes, each toe having a different length.

The above description of embodiments is not intended to be exhaustive or to limit the invention to the described forms. Specific embodiments of, and examples for, the invention are described herein for illustrative purposes, but various modifications are possible.

1. A substrate carrier comprising:
a carrier tray having a deposition surface;
a set of pedestal positions on the deposition surface, wherein the pedestal positions are adapted to receive a corresponding substrate pedestal, and wherein the pedestals have a working surface adapted to receive a substrate; and
one or more adjusters, each positioned in a corresponding pedestal position, wherein each adjuster can adjust a distance between the deposition surface and the working surface, an angular orientation of the working surface relative to the deposition surface, or both.

2. The substrate carrier of claim 1, further comprising one or more substrate pedestals, each positioned in a corresponding pedestal position.

3. The substrate carrier of claim 2 wherein at least one adjuster is positioned at a pedestal position between the pedestal position and the corresponding substrate pedestal.

4. The substrate carrier of claim 3 wherein the adjuster includes one or more shims.

5. The substrate carrier of claim 4 wherein the shims are wedge shims.

6. The substrate carrier of claim 1, further comprising a carrier base coupled to the carrier tray.

7. The substrate carrier of claim 6 wherein the carrier base includes a transport interface to couple the substrate carrier to a transport mechanism.

8. The substrate carrier of claim 7 wherein the transport interface includes a plurality of toes, each toe having a different length.

9. The substrate carrier of claim 1 wherein at least one pedestal position of the set of pedestal positions is bounded by stops positioned around at least part of the pedestal position.

10. The substrate carrier of claim 1 wherein at least one pedestal position of the set of pedestal positions is a depression in the carrier tray.

11. The substrate carrier of claim 1 wherein said set comprises an N×M array of pedestal positions, wherein N≥1 and M≥1.

12. A deposition system comprising:
a deposition chamber including a sputtering source and a transport system;
a substrate carrier coupled to the transport system to move one or more substrates through the deposition chamber, the substrate carrier including:
a carrier base including a transport interface to couple the substrate carrier to the transport system;
a carrier tray positioned and aligned on the carrier base, the carrier tray including:
a deposition surface,
an N×M set of pedestal positions on the deposition surface, wherein N≥1 and M≥1, and
one or more adjusters, each positioned in a corresponding pedestal position, wherein the adjuster can adjust a distance between the working surface and the sputtering source, an angular orientation of the working surface relative to the sputtering source, or both; and
one or more substrate pedestals, each positioned in a corresponding pedestal position, wherein each substrate pedestal has a working surface adapted to receive a substrate.

13. The deposition system of claim 12 wherein the carrier base includes a thick rigid web body.

14. The deposition system of claim 12 wherein the carrier base includes alignment pins that engage with corresponding alignment holes on the carrier tray, or wherein the carrier base includes alignment holes that engage with corresponding alignment pins on the carrier tray.

15. The deposition system of claim 12 wherein the adjuster is positioned in each pedestal position between the pedestal position and the corresponding substrate pedestal.

16. The deposition system of claim 15 wherein the adjuster includes one or more shims.

17. The deposition system of claim 16 wherein the shims are wedge shims.

18. The deposition system of claim 12 wherein at least one pedestal position of the set of pedestal positions is bounded by stops positioned around at least part of the pedestal position.

19. The deposition system of claim 12 wherein at least one pedestal position of the set of pedestal positions is a depression in the carrier tray.

20. The deposition system of claim 19 wherein the carrier base includes a transport interface to couple the substrate carrier to a transport mechanism.

21. The deposition system of claim 20 wherein the transport interface includes a plurality of toes, each toe having a different length.
